(19) United States
(12) Patent Application Publication
(10) Pub. No.: US 2013/0340523 A1
(43) Pub. Date: Dec. 26, 2013

(54) TUNING BAR PIEZOELECTRIC VIBRATOR AND TUNING FORK PIEZOELECTRIC VIBRATOR

(71) Applicant: Murata Manufacturing Co., Ltd., Nagaokakyo-shi (JP)

(72) Inventor: Haruyoshi KURAKAWA, Nagaokakyo-shi (JP)

(21) Appl. No.: 13/917,709

(22) Filed: Jun. 14, 2013

Related U.S. Application Data
(63) Continuation of application No. PCT/JP2011/072526, filed on Sep. 30, 2011.

(30) Foreign Application Priority Data
Dec. 16, 2010 (JP) 2010-280765

(51) Int. Cl. G01C 19/5607; H01L 41/107; G01C 19/5642; H01L 41/047

(52) U.S. Cl. CPC G01C 19/5607; H01L 41/047; H01L 41/107; G01C 19/5642
USPC 73/504.16; 310/366; 310/370; 73/504.15

(57) ABSTRACT

A tuning bar piezoelectric vibrator includes first and second leg portions defined by a tuning bar piezoelectric vibrator, layers of first and second inner driver electrodes arranged as inner driver electrodes between first and second piezoelectric layers that are polarized in opposite directions of a thickness direction, a first outer electrode and a second outer electrode arranged to face the first and the second inner driver electrodes with the piezoelectric layers in between, respectively, and first and second vibrator portions in which the inner driver electrodes are used as driver electrodes.

### BACKGROUND OF THE INVENTION

1. Field of the Invention

The present invention relates to piezoelectric vibrators, and more particularly to tuning bar piezoelectric vibrators and tuning fork piezoelectric vibrators, each of which includes first and second piezoelectric layers that are joined together so as that polarization directions thereof are opposite to each other in a thickness direction.

2. Description of the Related Art

In recent years, vibrating gyroscopes are widely used as anti-vibration sensors for digital cameras or rotational angular velocity sensor devices for automobile navigation. Conventionally, tuning fork piezoelectric vibrators are used as vibrators of such vibrating gyroscopes.

International Publication No. WO 2007/125615 discloses one example of tuning fork piezoelectric vibrator for use in a vibrating gyroscope. FIG. 16A and FIG. 16B are a top view and a bottom view of the tuning fork piezoelectric vibrator described in International Publication No. WO 2007/125615, respectively. In FIG. 16A, hatching is added on electrodes using parallel slanted lines to indicate, not a cross section, but positions of the electrodes.

A tuning fork piezoelectric vibrator 1001 includes a pair of leg parts 1002, 1003 and a base part 1004 to which one ends of the leg parts 1002, 1003 are connected. In other words, the pair of leg parts 1002, 1003 is formed by forming a slit 1005 in a rectangular piezoelectric substrate. In FIG. 16A, portions illustrated with thick black lines are grooves 1006, 1007 formed on a top surface of the piezoelectric substrate.

FIG. 16C illustrates a cross-section of part formed of the leg parts 1002, 1003. In the tuning fork piezoelectric vibrator 1001, the piezoelectric substrate is configured such that a first piezoelectric layer 1008 and a second piezoelectric layer 1009 are stacked on top of each other. A floating electrode 1010 is formed between the piezoelectric layers 1008, 1009. Poling is performed so as that the piezoelectric layer 1008 and the piezoelectric layer 1009 have opposite polarization directions in a thickness direction as illustrated by arrows in the figures.

Electrodes 1011 to 1013 are formed on a top surface of the piezoelectric layer 1008. The electrodes 1011, 1013 are formed on outer side regions of the grooves 1006, 1007. The electrode 1012 is formed in a region between the grooves 1006, 1007.

In the tuning fork piezoelectric vibrator 1001, the electrodes 1011, 1013 are used as driver or detector electrodes, and the electrode 1012 is used as a detector or driver electrode.

In the piezoelectric vibrator 1001, the electrode 1012 that serves as the driver or detector electrode is connected to an oscillator circuit that is not illustrated in the drawing. According to this arrangement, the oscillation occurs in such a way that a state where tips of the leg parts 1002 and 1003 move away from each other and a state where the tips move closer to each other are repeated alternately. Furthermore, in the case where the piezoelectric vibrator 1001 is used as a vibrator of vibrating gyroscope, vibration directions of the leg parts 1002 and 1003 change when a rotational angular velocity is applied. This change causes the electrodes 1012, 1013 to generate signals in reversed phases corresponding to the Coriolis force, making it possible to detect the rotational angular velocity.

In the tuning fork piezoelectric vibrator 1001 described in International Publication No. WO 2007/125615, a metal film that serves as an electrode is not formed on a bottom surface of the piezoelectric substrate. Accordingly, it is expected that temperature characteristics may be improved since no metal film is formed on a portion where stress is applied during operation.

However, in the tuning fork piezoelectric vibrator 1001, only the piezoelectric layer 1008 exhibits a piezoelectricity effect in the piezoelectric substrate. In other words, despite providing a structure in which the piezoelectric layer 1008 and the piezoelectric layer 1009 are stacked on top of each other, only the piezoelectric layer 1008 sandwiched between the electrodes 1011 to 1013 and the internal floating electrode 1010 exhibits the piezoelectricity effect. Thus, driving efficiency is not sufficiently high. For example, it is difficult to improve sensitivity when the device is used as a sensor for detecting the rotational angular velocity.

In order to utilize the piezoelectricity effect of the piezoelectric layer 1009, one idea is to additionally form a driver electrode on the bottom surface of the piezoelectric layer 1009. However, in the tuning fork piezoelectric vibrator 1001, it is strongly required that electrode areas of the leg parts 1002, 1003 be equal to each other in the pair of leg parts 1002, 1003. When the driver electrode is also formed on the bottom surface of the piezoelectric layer 1009, namely, when the electrode 1011 that serves as the driver electrode is formed on the top surface of the piezoelectric layer 1008 and the driver electrode is formed on the bottom surface of the piezoelectric layer 1009, it would be difficult to balance the areas of driver electrodes between the leg part 1002 and the leg part 1003. Furthermore, in the tuning fork piezoelectric vibrator 1001, the electrodes 1011, 1012 function not only as the driver electrodes but also as the detector electrodes. Thus, there is a problem that arranging the electrodes 1011 to 1013 so as to improve both the driving efficiency and detecting efficiency is difficult to achieve.

### SUMMARY OF THE INVENTION

Preferred embodiments of the present invention provide a tuning bar piezoelectric vibrator and a tuning fork piezoelectric vibrator, each of which improves driving efficiency by utilizing the piezoelectricity effect of plural piezoelectric layers, enables easy designing and fabricating of electrodes, and provides higher design flexibility.

A tuning bar piezoelectric vibrator according to a preferred embodiment of the present invention includes a first piezoelectric layer polarized in a thickness direction; a second piezoelectric layer polarized in a direction opposite to the first piezoelectric layer in the thickness direction, the second piezoelectric layer being stacked on the first piezoelectric layer; a first inner driver electrode and a second inner driver electrode layered between the first and second piezoelectric layers, the first inner driver electrode and the second inner driver electrode being separated from each other in a plane direction of an interface between the first and second piezoelectric layers; a first outer electrode arranged on an outer surface of the first piezoelectric layer so as to face the inner driver electrode over the first piezoelectric layer; and a second outer electrode arranged on an outer surface of the second piezoelectric layer so as to face the inner driver electrode over the second piezoelectric layer.

In the tuning bar piezoelectric vibrator according to a preferred embodiment of the present invention, the first inner driver electrode and the second inner driver electrode is arranged at the same position or different positions in a direction perpendicular or substantially perpendicular to the interface.

Furthermore, a characteristic adjustment layer may be provided on at least one of outer sides of the first and second outer electrodes. The characteristic adjustment layer may be made of a material different from or the same as that of the first and second piezoelectric layers. Characteristics of the tuning bar piezoelectric vibrator may be easily adjusted by selecting the material or the thickness of the characteristic adjustment layer.

According to still another specific aspect of a tuning bar piezoelectric vibrator according to a preferred embodiment of the present invention, a groove is arranged so as to extend in the thickness direction of the second piezoelectric layer and penetrate through at least the second piezoelectric layer, the second piezoelectric layer is divided into a first division piezoelectric layer portion and a second division piezoelectric layer portion by the groove, and the second outer electrode includes a first division outer electrode and a second division outer electrode arranged on outer surfaces of the first division piezoelectric layer portion and the second division piezoelectric layer portion. The tuning bar piezoelectric vibrator further includes a first conduction member that defines a conduction path between the first division outer electrode and the second division outer electrode.

In a preferred embodiment of the present invention, the groove may be arranged so as to penetrate through the first and second piezoelectric layers. By this arrangement, the first piezoelectric layer is divided into a third division piezoelectric layer portion and a fourth division piezoelectric layer portion. In this case, the groove includes a jointing material layer that joins the first division piezoelectric layer portion and the third division piezoelectric layer portion to the second division piezoelectric layer portion and the fourth division piezoelectric layer portion. In this arrangement, the first outer electrode is divided into a third division outer electrode and a fourth division outer electrode with the groove in between. The tuning bar piezoelectric vibrator further includes a second conduction member that establishes an electrical contact between the third and fourth division outer electrodes.

A tuning fork piezoelectric vibrator according to a preferred embodiment of the present invention is a tuning fork piezoelectric vibrator having a tuning fork shape and including first and second leg portions extending in a length direction, the first and second leg portions facing each other over a groove; and a base portion connected to first ends of the first and second leg portions, wherein a structure including the first leg portion and the second leg portion includes tuning bar piezoelectric vibrators, at least one of which is provided in accordance with a preferred embodiment of the present invention.

According to one specific aspect of the tuning fork piezoelectric vibrator according to a preferred embodiment of the present invention, the first leg portion and the second leg portion are each defined by the tuning bar piezoelectric vibrator according to a preferred embodiment of the present invention.

According to another specific aspect of the tuning fork piezoelectric vibrator according to a preferred embodiment of the present invention, in the tuning bar piezoelectric vibrator, the groove is arranged so as to extend in the thickness direction of the second piezoelectric layer and penetrate through at least the second piezoelectric layer. The second piezoelectric layer is divided into a first division piezoelectric layer portion and a second division piezoelectric layer portion by the groove. The second outer electrode includes a first division outer electrode and a second division outer electrode located on outer surfaces of the first division piezoelectric layer portion and the second division piezoelectric layer portion. The tuning fork piezoelectric vibrator further includes a first conduction member that defines a conduction path between the first division outer electrode and the second division outer electrode. The first leg portion includes the first division piezoelectric layer portion and the first division outer electrode located on one side of the groove, and the second leg portion includes the second division piezoelectric layer portion and the second outer electrode located on the other side of the groove, allowing the first and second leg portions to be defined by a single piece of the tuning bar piezoelectric vibrator.

According to still another specific aspect of the tuning fork piezoelectric vibrator according to a preferred embodiment of the present invention, the groove is arranged so as to penetrate through the first and second piezoelectric layers; the first piezoelectric layer is divided into a third division piezoelectric layer portion and a fourth division piezoelectric layer portion by the groove; the groove includes a jointing material layer that joins the first division piezoelectric layer portion and the third division piezoelectric layer portion to the second division piezoelectric layer portion and the fourth division piezoelectric layer portion; and the first outer electrode is divided into a third division outer electrode and a fourth division outer electrode with the groove in between. The tuning fork piezoelectric vibrator further includes a second conduction member that establishes an electrical contact between the third and fourth division outer electrodes.

According to still another specific aspect of the tuning bar or the tuning fork piezoelectric vibrator according to a preferred embodiment of the present invention, a tuning bar piezoelectric vibrator or a tuning fork piezoelectric vibrator for use in a gyroscope module to detect rotational angular velocity is provided. In that case, the inner driver electrode is used as a driver electrode, and at least one of the first and second outer electrodes is used as a detector electrode.

The tuning bar piezoelectric vibrator according to a preferred embodiment of the present invention is configured such that the first piezoelectric layer is sandwiched between the first outer electrode and the first and second inner driver electrodes that are separated from each other in the plane direction of the interface between the first and second piezoelectric layers. Furthermore, the second piezoelectric layer is sandwiched between the second outer electrode and the first and second inner driver electrodes. Thus, the piezoelectricity effect of both the first and second piezoelectric layers is utilized. Thus, for example, when the tuning bar piezoelectric vibrator according to a preferred embodiment of the present invention is used as a vibrator of vibrating gyroscope, the driving efficiency is improved. Furthermore, the first and second inner driver electrodes are the driver electrodes, and the first and second outer electrodes are provided on the outer surfaces of the first and second piezoelectric layers. Thus, the areas of the first and second outer electrodes are easily balanced between a portion where the first inner driver electrode is located and a portion where the second inner driver electrode is provided. Thus, the flexibility in designing is improved.

In particular, when the first and second inner driver electrodes are separated from each other by the groove that is arranged so as to penetrate through at least one of the first piezoelectric layer and the second piezoelectric layer, a tuning fork piezoelectric vibrator with excellent driving efficiency is achieved in accordance with a preferred embodiment of the present invention.

Furthermore, the first and second outer electrodes are used as the detector electrodes, and the first and second inner driver electrodes are used as the driver electrodes. Thus, electrode designing and processing are easily performed. Accordingly, the flexibility in designing is also be improved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A and FIG. 1B are a perspective view and a cross-sectional view of a tuning bar piezoelectric vibrator according to a first preferred embodiment of the present invention.

FIG. 2 is a cross-sectional view of a first modification example of the tuning bar piezoelectric vibrator according to the first preferred embodiment of the present invention.

FIG. 3 is a cross-sectional view of a second modification example of the tuning bar piezoelectric vibrator according to the first preferred embodiment of the present invention.

FIG. 4 is a cross-sectional view of a third modification example of the tuning bar piezoelectric vibrator according to the first preferred embodiment of the present invention.

FIG. 5 is a cross-sectional view of a tuning bar piezoelectric vibrator according to a second preferred embodiment of the present invention.

FIG. 6 is a cross-sectional view of a first modification example of the tuning bar piezoelectric vibrator according to the second preferred embodiment of the present invention.

FIG. 7 is a cross-sectional view of a second modification example of the tuning bar piezoelectric vibrator according to the second preferred embodiment of the present invention.

FIG. 8 is a cross-sectional view of a tuning fork piezoelectric vibrator according to a third preferred embodiment of the present invention.

FIG. 9A, FIG. 9B, and FIG. 9C are schematic plan views illustrating an electrode configuration on a first piezoelectric layer, an electrode configuration at an interface between the first piezoelectric layer and a second piezoelectric layer, and an electrode configuration located on a bottom surface of the second piezoelectric layer, respectively, of the tuning fork piezoelectric vibrator according to the third preferred embodiment of the present invention.

FIG. 10 is a cross-sectional view of a tuning fork piezoelectric vibrator according to a third preferred embodiment of the present invention.

FIG. 11A to FIG. 11D are schematic plan views illustrating electrode configurations of the tuning fork piezoelectric vibrator according to the third preferred embodiment of the present invention where FIG. 11A is a plan view of a portion where detector electrodes are provided, FIG. 11B is a schematic plan view illustrating an electrode configuration located on a first piezoelectric layer, FIG. 11C is a schematic plan view illustrating an electrode configuration of inner driver electrodes located at an interface between the first piezoelectric layer and a second piezoelectric layer, and FIG. 11D is a schematic plan view illustrating an electrode configuration located on a bottom surface of the second piezoelectric layer.

FIG. 12 is a cross-sectional view of the tuning fork piezoelectric vibrator according to the fourth preferred embodiment of the present invention.

FIG. 13A, FIG. 13B, and FIG. 13C are schematic plan views illustrating an electrode configuration on a first piezoelectric layer, an electrode configuration at an interface between the first piezoelectric layer and a second piezoelectric layer, and an electrode configuration located on a bottom surface of the second piezoelectric layer, respectively, of the tuning fork piezoelectric vibrator according to the fourth preferred embodiment of the present invention.

FIG. 14 is a diagram illustrating impedance characteristics in driving mode for a tuning fork piezoelectric vibrator according to a fifth preferred embodiment of the present invention, and a comparison example 1 and a comparison example 2 of the tuning fork piezoelectric vibrator.

FIG. 15 is a diagram illustrating impedance characteristics in detecting mode for the tuning fork piezoelectric vibrator according to the fifth preferred embodiment of the present invention, and the comparison example 1 and the comparison example 2 of the tuning fork piezoelectric vibrator.

FIG. 16A is a plan view of a conventional tuning fork piezoelectric vibrator, and FIG. 16B is a bottom view thereof. FIG. 16C is a cross-sectional view of a portion where a pair of leg portions is provided. FIG. 16D is a cross-sectional view of a base portion.

### DETAILED DESCRIPTION OF THE PREFERRED EMBODIMENTS

Hereinafter, the present invention is disclosed in detail by describing specific preferred embodiments of the present invention with reference to the drawings.

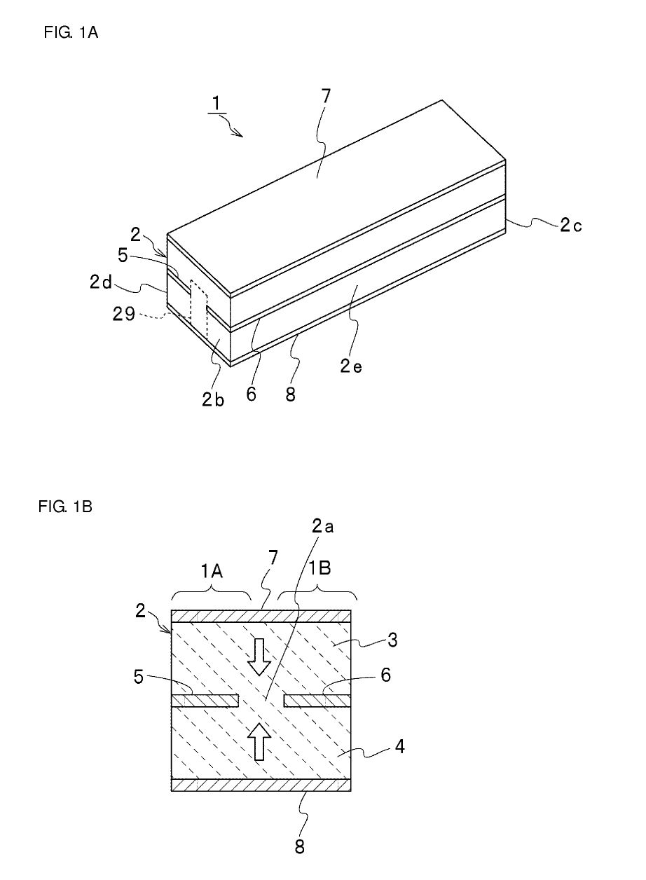

FIG. 1A and FIG. 1B are a perspective view and a cross-sectional view of a tuning bar piezoelectric vibrator according to a first preferred embodiment of the present invention.

A tuning bar piezoelectric vibrator 1 includes a long-and-narrow strip shaped piezoelectric body 2. In other words, the piezoelectric body 2 with a long-and-narrow rectangle planar shape is preferably used.

The piezoelectric body 2 is preferably made of piezoelectric ceramics such as PZT based ceramics. As illustrated in FIG. 1B, the piezoelectric body 2 includes a first piezoelectric layer 3 on the upper side and a second piezoelectric layer 4 on the lower side. A first inner driver electrode 5 and a second inner driver electrode 6 are provided at an interface between the first piezoelectric layer 3 and the second piezoelectric layer 4.

In the present preferred embodiment, the first inner driver electrode 5 and the second inner driver electrode 6 are arranged inside the piezoelectric body 2 at the same height. In other words, on the same plane, the first inner driver electrode and the second inner driver electrode 6 face to each other along a gap 2a that extends in a length direction of the piezoelectric body 2.

As illustrated in FIG. 1A, the first and second inner driver electrodes 5, 6 are exposed at a pair of end surfaces 2b, 2c of the piezoelectric body 2. Furthermore, the first inner driver electrode 5 is exposed at a side surface 2d, and the second inner driver electrode 6 is exposed at a side surface 2e. However, it is not required that the first and second inner driver electrodes 5, 6 be exposed at an outer surface of the piezoelectric body 2. It is preferable that the first and second inner driver electrodes 5, 6 be exposed at the outer surface of the piezoelectric body 2 as in the present preferred embodiment since such an arrangement improves the driving efficiency.

The first and second inner driver electrodes 5, 6 may be connected to different electric potentials when in use, as will be described later.

The first and second inner driver electrodes 5, 6 may be made of a suitable metal material such as Ag, Cu, Al, an alloy of some of these metals, or the like. A structure including the first and second inner driver electrodes 5, 6 and the first and second piezoelectric layers 3, 4 may be obtained by using a well-known ceramics co-firing technology, for example.

The first piezoelectric layer 3 and the second piezoelectric layer 4 are polarized in a thickness direction. However, as illustrated in FIG. 1B, the polarization direction of the first piezoelectric layer 3 and the polarization direction of the second piezoelectric layer 4 are opposite to each other.

On a top surface of the piezoelectric body 2, a first outer electrode 7 is provided. On a bottom surface of the piezoelectric body 2, a second outer electrode 8 is provided. The first and second outer electrodes 7, 8 are arranged so as to cover the entire areas of the top surface and the bottom surface of the piezoelectric body 2, respectively. However, it is not always required that the first and second outer electrodes 7, 8 be each arranged throughout the entirety of the corresponding area of the top surface and the bottom surface of the piezoelectric body 2 as long as the first and second outer electrodes 7, 8 are capable of facing the first and second inner driver electrodes 5, 6.

The first and second outer electrodes 7, 8 may be made of a suitable metal material such as Ag, Cu, Al, alloy of some of those metals, or the like. A fabrication method of the first and second outer electrodes 7, 8 is not limited to any particular method, and the first and second outer electrodes 7, 8 may be formed by deposition, plating, sputtering, coating of electrically conductive paste, or other suitable process, for example.

The tuning bar piezoelectric vibrator 1 of the present preferred embodiment may be used as, for example, a vibrator to detect the angular velocity such as a vibrating gyroscope, for example. When in use, the first inner driver electrode 5 and the second inner driver electrode 6 are preferably used as driver electrodes. However, different electric potentials are fed to the first inner driver electrode 5 and the second inner driver electrode 6.

The first outer electrode 7 and the second outer electrode 8 are preferably used as detector electrodes. In that case, in the tuning bar piezoelectric vibrator 1 of the present preferred embodiment, the piezoelectric body 2 may be driven by a layer of the first and second inner driver electrodes 5, 6 provided at a layer of an interface between the first and second piezoelectric layers 3, 4.

Here, a portion of the piezoelectric body where the first inner driver electrode 5 is located is referred to as a first vibrator portion 1A, and portion of the piezoelectric body where the second inner driver electrode 6 is located is referred to as a second vibrator portion 1B.

In the first vibrator portion 1A, the first inner driver electrode 5 faces the first outer electrode 7 with the first piezoelectric layer 3 in between, and further faces the second outer electrode 8 with the second piezoelectric layer 4 in between. Similarly, in the second vibrator portion 1B, the second inner driver electrode 6 faces the first outer electrode 7 with the first piezoelectric layer 3 in between, and faces the second outer electrode 8 with the second piezoelectric layer 4 in between. Thus, in the vibrator portion 1A and the vibrator portion 1B, the vibrator portion 1A, 1B may be driven by utilizing the piezoelectricity effect of the first and second piezoelectric layers 3, 4.

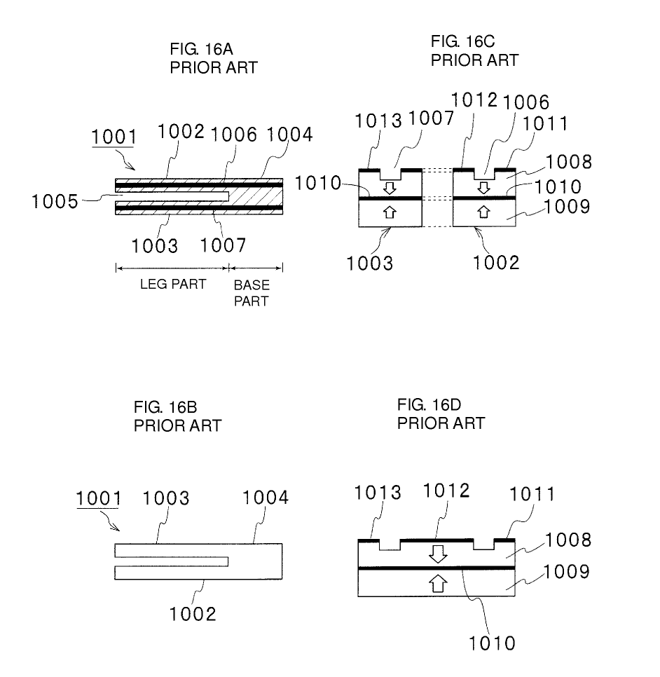

The tuning fork piezoelectric vibrator 1001 illustrated in FIGS. 16A-16D has a structure in which the piezoelectric layers 1008, 1009 are stacked on top of each other, and is driven by utilizing the piezoelectricity effect of the piezoelectric layer 1008. Thus, the piezoelectric layer 1009 is not used for driving, reducing the driving efficiency to a lower value.

On the other hand, in the present preferred embodiment, both the piezoelectric layers 3, 4 are utilized, and the driving efficiency is effectively improved.

Furthermore, in the present preferred embodiment, the first and second inner driver electrodes 5, 6 are provided at the interface between the first and second piezoelectric layers 3, 4, namely, on the same plane. Accordingly, the piezoelectric body 2 may be obtained effectively by using a well-known ceramics co-firing technology, for example. Furthermore, the first and second inner driver electrodes 5, 6 are formed highly accurately on a piezoelectric green sheet by printing inner electrode paste or the like. Accordingly, the ratio of electrode areas in the vibrator portion 1A and the vibrator portion 1B are controlled highly accurately and easily.

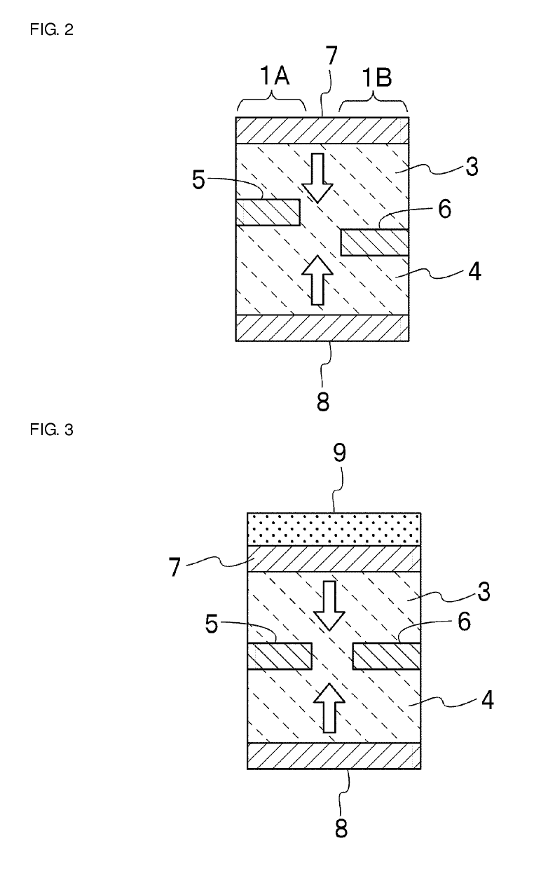

FIG. 2 to FIG. 4 are cross-sectional views respectively illustrating modification examples of the tuning bar piezoelectric vibrator 1 according to the foregoing preferred embodiment.

In the first modification example illustrated in FIG. 2, height positions of the first inner driver electrode 5 and the second inner driver electrode 6 are different from each other. The remaining aspects of the first modification example are the same as those of the foregoing tuning bar piezoelectric vibrator 1.

As in the first modification example, the height positions of the first inner driver electrode 5 and the second inner driver electrode 6 may be made different from each other. Such a structure may also be formed easily by using a well-known ceramics co-firing technology, for example. In other words, when stacking a plurality of piezoelectric green sheets to obtain the piezoelectric body 2, the first inner driver electrode 5 and the second inner driver electrode 6 may be formed on different piezoelectric green sheets.

However, in that case, the first and second piezoelectric layers 3, 4 have different thicknesses in the first vibrator portion 1A and the second vibrator portion 1B. In other words, as illustrated in FIG. 2, a portion of the first piezoelectric layer 3 above the first inner driver electrode 5 may be either thinner or thicker than portion of the first piezoelectric layer 3 above the second inner driver electrode 6.

In the second modification example illustrated in FIG. 3, an additional layer 9 is provided on the top surface of the first external driver electrode 5 as a characteristic adjustment layer. The remaining aspects of the second modification example are the same as those of the foregoing tuning bar piezoelectric vibrator 1. As described above, the additional layer 9 composed of a material different from the first and second piezoelectric layers 3, 4 may be provided. Alternatively, the additional layer may be provided on the bottom surface of the second outer electrode 8, or on both outer sides of the first and second outer electrodes 7, 8.

The material for forming the additional layer 9 may be suitably selected depending on its purpose. For example, forming the additional layer 9 made of a material with superior cutting characteristics allow easy frequency adjustment by performing additional processing. Alternatively, forming the additional layer 9 of a material with high fracture strength increases fracture strength of vibrator.

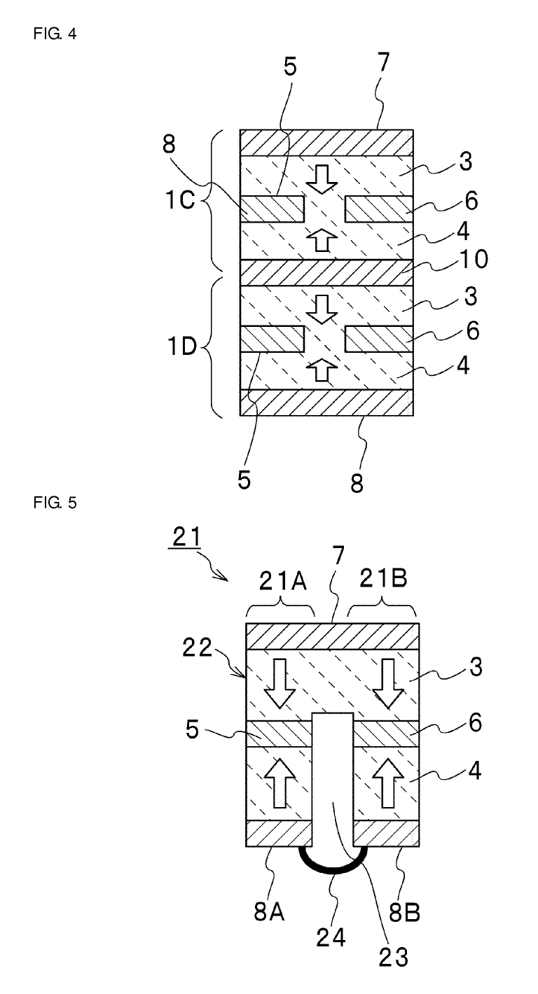

The third modification example illustrated in FIG. 4 has a structure in which two layers of the tuning bar piezoelectric vibrator 1 illustrated in FIGS. 1A and 1B are stacked on top of each other. In other words, a first tuning bar piezoelectric vibrators 1C is stacked on top of a second tuning bar piezoelectric vibrators 1D. Thus, an inner electrode 10 functions as the second outer electrode of the tuning bar piezoelectric vibrator 1C and as the first outer electrode of the tuning bar piezoelectric vibrator 1D. In this way, plural layers of the tuning bar piezoelectric vibrator 1 of the first preferred embodiment may be stacked on top of each other in the thickness direction. The number of stacking layers may be three or more, for example.

FIG. 5 is a cross-sectional view of a tuning bar piezoelectric vibrator 21 according to a second preferred embodiment of the present invention. The tuning bar piezoelectric vibrator 21 is preferably provided by using a strip shaped piezoelectric body 22 as is the case with the tuning bar piezoelectric vibrator 1 of the first preferred embodiment. However, a groove 23 is provided in the bottom surface of the piezoelectric body 22. The groove 23 may be formed by processing a strip shaped piezoelectric body from the bottom surface and upward to form a groove as illustrated in FIG. 1A with a dashed line 29.

The piezoelectric body 22 is configured similarly to the piezoelectric body 2 of the first preferred embodiment except that the groove 23 is provided in the piezoelectric body 22. The foregoing groove 23 is located in a portion corresponding to a portion where the gap 2a of FIG. 1B is located. The groove 23 is preferably arranged throughout the entire length of the piezoelectric body 22. Furthermore, in the present preferred embodiment, the groove 23 cuts through the second piezoelectric layer 4 in the thickness direction and reaches a lower portion of the first piezoelectric layer 3. However, the depth of the groove 23, namely, the size of the piezoelectric body 22 in a height direction is not limited to any particular value.

In the present preferred embodiment, by forming the groove 23, the second outer electrode 8 is divided into a first division outer electrode 8A and a second division outer electrode 8B. The first inner driver electrode 5 is arranged on one side of the groove 23, and the second inner driver electrode 6 is arranged on the other side. Thus, the first vibrator portion 21A is located on one side of the groove 23, and the second vibrator portion 21B is located on the other side.

Furthermore, the first division outer electrode 8A and the second division outer electrode 8B are electrically connected through a bonding wire 24 that serves as a conduction member. Instead of using the bonding wire 24, any suitable electrically conductive connecting agent may be used, or members in a portion to which the vibrator is bonded may be used to provide a conduction path.

The tuning bar piezoelectric vibrator 21 of the present preferred embodiment is similar to that of the first preferred embodiment except that the second outer electrode 8 is divided into the first division outer electrode 8A and the second division outer electrode 8B with formation of the groove 23 and that the bonding wire 24 is provided as the conduction member. Thus, like reference numerals denote like elements, and descriptions thereof are omitted.

To obtain the foregoing piezoelectric body 22, first, a structure prior to the formation of the groove 23, namely, the piezoelectric body 2 illustrated in FIGS. 1A and 1B is obtained by using a well-known ceramics co-firing technology. Subsequently, the groove 23 is formed.

To drive, a voltage is applied across the first inner driver electrode 5 and the second inner driver electrode 6 to drive the first and second vibrator portions 21A, 21B.

In this case, the first and second division outer electrodes 8A, 8B are electrically connected through the bonding wire 24. This ensures that both the vibrator portion 21A and the vibrator portion 21B are reliably driven. In the present preferred embodiment, the piezoelectricity effect of both the first and second piezoelectric layers 3, 4 may also be utilized for driving. Thus, the driving efficiency is improved.

In the second preferred embodiment, what is required is to first obtain the structure similar to that of the piezoelectric body 2 of the first preferred embodiment by using a well-known ceramics co-firing technology and then form the groove 23. Thus, the first and second vibrator portions 21A, 21B are formed easily and highly accurately. Furthermore, an electrode structure of the first vibrator portion 21A and an electrode structure of the second vibrator portion 21B may be balanced easily and reliably.

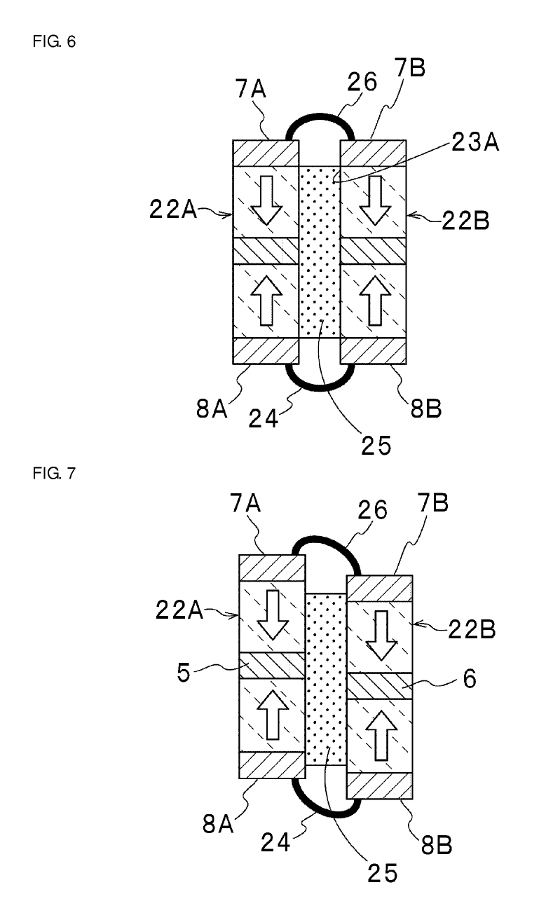

FIG. 6 is a cross-sectional view of a first modification example of the tuning bar piezoelectric vibrator 21 according to the second preferred embodiment. In the present modification example, the groove 23A cut through the piezoelectric body 22. Thus, the piezoelectric body 22 is divided into a first piezoelectric body 22A and a second piezoelectric body 22B so as to separate the first vibrator portion 21A and the second vibrator portion 21B. However, the first piezoelectric body 22A and the second piezoelectric body 22B are joined together with a jointing material 25 that fills the groove 23A. As described above, the groove may be formed so as to cut through the piezoelectric body in the thickness direction. The jointing material 25 may be any suitable adhesive. For example, an insulating adhesive agent such as an epoxy based adhesive agent or the like may be used.

In the present preferred embodiment, the piezoelectric body is divided into the first and second piezoelectric bodies 22A, 22B. Thus, the first outer electrode is also divided into a third division outer electrode 7A and a fourth division outer electrode 7B. Furthermore, the third division outer electrode 7A and the fourth division outer electrode 7B are electrically connected through a bonding wire 26 that serves as a conduction member. Alternatively, as is the case with the bonding wire 24, the bonding wire 26 may be replaced with another electrically conductive jointing material.

The present modification example may be driven as is the case with the tuning bar piezoelectric vibrator 21 since, in the first and second outer electrodes, the bonding wire 24 electrically connects the first division outer electrode 8A and the second division outer electrode 8B, and the bonding wire 26 electrically connects the third division outer electrode 7A and the fourth division outer electrode 7B.

Furthermore, the remaining structure is similar to that of the tuning bar piezoelectric vibrator 21. Thus, similar effects are obtained.

Alternatively, as in a third modification example illustrated in FIG. 7, the first piezoelectric body 22A and the second piezoelectric body 22B may be joined together with the jointing material 25 so as to have different height positions. In this case, the height positions of the first inner driver electrode 5 and the second inner driver electrode 6 are different from each other. In other words, it is not always necessary that the first and second inner driver electrodes 5, 6 are in the same height position even in the second preferred embodiment.

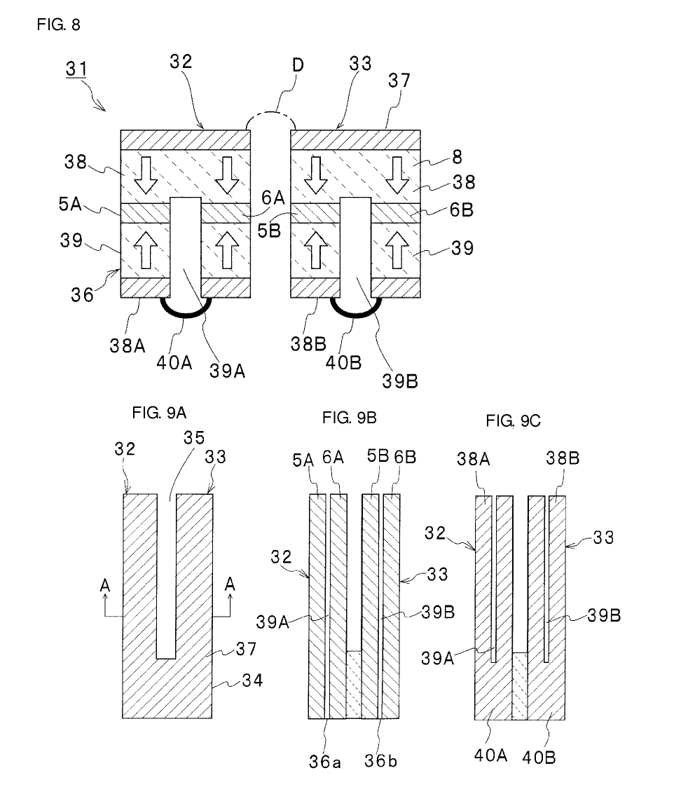

FIG. 8 is a cross-sectional view of a tuning fork piezoelectric vibrator according to a third preferred embodiment of the present invention. FIG. 9A to FIG. 9C are schematic plan views respectively illustrating electrode configurations of the tuning fork piezoelectric vibrator at different height positions.

A tuning fork piezoelectric vibrator 31 of the present preferred embodiment corresponds to a tuning fork piezoelectric vibrator in which a pair of leg portions is provided with the tuning bar piezoelectric vibrator 21 of the second preferred embodiment.

FIG. 8 is the cross-sectional view of a portion where a first leg portion 32 and a second leg portion 33 of the tuning fork piezoelectric vibrator 31 are provided. FIG. 9A is the plan view of the tuning fork piezoelectric vibrator 31. The cross-sectional view of FIG. 8 illustrates the cross section cut along the line A-A of FIG. 9A.

The tuning fork piezoelectric vibrator 31 includes the first leg portion 32, the second leg portion 33, and a base portion 34. The base portion 34 is portion to which first ends of the first and second leg portions 32, 33 having long-and-narrow rectangle strip shapes are joined.

A tip of the first leg portion 32 and a tip of the second leg portion 33 are separated by a slit 35 that serves as a groove. A piezoelectric body 36, from which the tuning fork piezoelectric vibrator 31 is formed, may be obtained by forming the slit 35 in a long-and-narrow rectangle plate shaped piezoelectric body from its center and extending in the length direction.

A first outer electrode 37 is provided on a top surface of the piezoelectric body 36. The first outer electrode 37 is provided on top surfaces of the first and second leg portions 32, 33 as well as on a top surface of the base portion 34. A dashed line D of FIG. 8 schematically illustrates the first outer electrode 37 arranged on the base portion 34. In other words, the first outer electrodes 37 on the first and second leg portions 32, 33 preferably are integrally formed so as to be defined by a unitary monolithic element.

The piezoelectric body 36 includes a first piezoelectric layer 38 and a second piezoelectric layer 39 that is stacked on a bottom surface of the first piezoelectric layer 38. The first and second piezoelectric layers 38, 39 are polarized in the thickness direction. However, the polarization directions of the piezoelectric layers 38, 39 are opposite to each other as illustrated with arrows in FIG. 8.

At interfaces between the first piezoelectric layer 38 and the second piezoelectric layer 39, first inner driver electrodes 5A, 5B and second inner driver electrodes 6A, 6B illustrated in FIG. 9B are provided. In other words, the first and second inner driver electrodes 5A, 6A are provided in the first leg portion 32, and the first and second inner driver electrodes 5B, 6B are provided in the second leg portion 33.

In the present preferred embodiment, the first inner driver electrodes 5A, 5B and the second inner driver electrodes 6A, 6B have long-and-narrow strip shapes. In other words, in the first leg portion 32 having a long-and-narrow strip shape, the first and second inner driver electrodes 5A, 6A face each other over a gap 36a, and, in the second leg portions 33 having a long-and-narrow strip shape, the first and second inner driver electrodes 5B, 6B face each other over a gap 36b. The second inner driver electrode 6A and the first inner driver electrode 5B, both of which are arranged on inner sides, are electrically insulated.

Furthermore, as illustrated in FIG. 9C, outer electrodes 38A, 38B are provided on the bottom surface of the piezoelectric body 36.

The outer electrode 38A is arranged so as to extend from the bottom surface of the first leg portion 32 to the base portion 34. Similarly, the outer electrode 38B is arranged so as to extend from the bottom surface of the second leg portion 33 to the base portion 34. However, the outer electrode 38A and the outer electrode 38B are electrically insulated from each other at the bottom surface of the base portion 34.

In the first and the second leg portions 32, 33, grooves 39A, 39B are respectively provided. The grooves 39A, 39B are similar to the groove 23 of the tuning bar piezoelectric vibrator 21 of the second preferred embodiment. Thus, in the first leg portion 32, the outer electrode 38A is separated by the groove 39A. However, the outer electrodes on both sides of the groove 39A are connected to each other at the bottom surface of the base portion 34. In other words, a conduction member 40A illustrated in FIG. 8 is defined by a portion of the outer electrode 38A that extends to the bottom surface of the base portion 34.

Similarly, a conduction member 40B illustrated in FIG. 8 is defined by a portion of the outer electrode 38B that extends to the bottom surface of the base portion 34.

As is evident from comparison between FIGS. 9A-9C and the tuning bar piezoelectric vibrator 21 of the second preferred embodiment illustrated in FIG. 5, each of the first leg portion 32 and the second leg portion 33 corresponds to the tuning bar piezoelectric vibrator 21, and a structure in which two of these tuning bar piezoelectric vibrators 21 are connected at the base portion 34 corresponds to the tuning fork piezoelectric vibrator 31 of the present preferred embodiment.

Thus, the tuning fork piezoelectric vibrator 31 is easily obtained by using a fabrication method similar to the one used for fabricating the tuning bar piezoelectric vibrator 21 except an additional process to form the slit 35.

When driving the tuning fork piezoelectric vibrator 31 of the present preferred embodiment, voltages are respectively applied between the first and second inner driver electrodes 5A, 6A and between the first and second inner driver electrodes 5B, 6B to start oscillation in the piezoelectric body 36. In this case, both the first and second piezoelectric bodies 38, 39 may be utilized. Thus, the driving efficiency is improved. Furthermore, as described above, the piezoelectric body 36 may be obtained by using a well-known ceramics co-firing technology, for example. Thus, the electrode structures of vibrator portions on both sides of the groove 39A and the groove 39B may be balanced easily and highly accurately in the first leg portion 32 and the second leg portion 33, respectively.

When driving, the first inner driver electrode 5A and the first inner driver electrode 5B are kept at the same electric potential. Furthermore, the second inner driver electrode 6A and the second inner driver electrode 6B are kept at the same electric potential. However, the first inner driver electrodes 5A, 5B and the second inner driver electrode 6A, 6B are at different electric potentials. In this way, the tuning fork piezoelectric vibrator 31 may be driven.

Furthermore, when being used as a vibrator of vibrating gyroscope, the outer electrodes 38A, 38B may be used as the detector electrodes. Alternatively, the first outer electrode 37 may be used as the detector electrode.

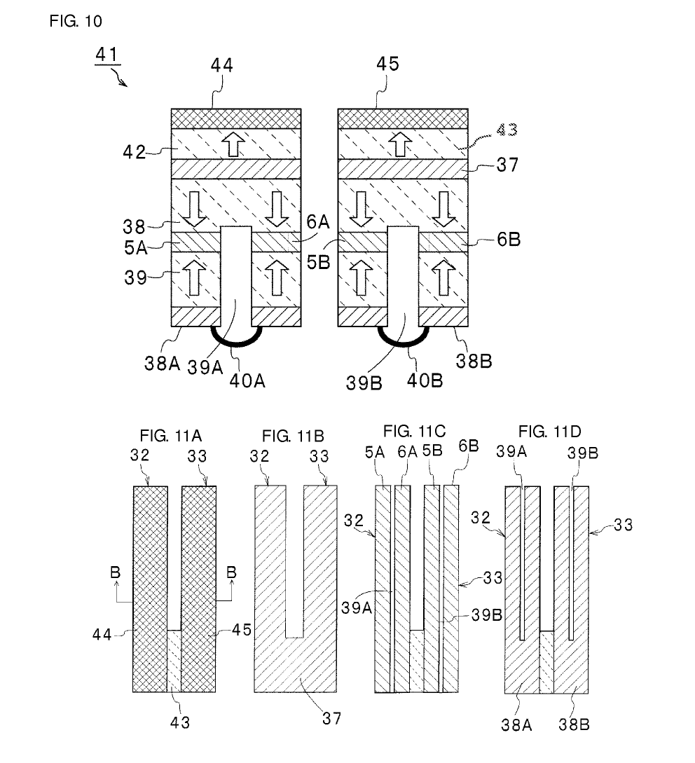

FIG. 10 and FIG. 11A to FIG. 11D are a cross-sectional view of a modification example of the tuning fork piezoelectric vibrator of the third preferred embodiment and its plan views illustrating electrode configurations at different height positions, respectively. FIG. 10 illustrates the cross section cut along the B-B line in FIG. 11A. Differences of the present modification example from the third preferred embodiment are that a piezoelectric layer 42 is additionally stacked on the top surface of the first outer electrode 37 and detector electrodes 44, 45 are provided on the piezoelectric layer 42. The remaining aspects are the same as those of the third preferred embodiment. Thus, like reference numerals denote like elements and descriptions thereof are omitted.

The piezoelectric layers 42, 43 are polarized in the thickness direction. The polarization of the piezoelectric layers 42, 43 may be performed such that the piezoelectric layers 42, 43 are polarized in a forward direction or a backward direction with respect to that of the first piezoelectric layer 38 in the thickness direction. The piezoelectric layer 42 may be composed of the same piezoelectric material as that of the first and second piezoelectric layers described above, or may be composed of a different piezoelectric material.

The detector electrodes 44, 45 may be formed of a suitable metal material such as Ag, Pd, Cu, alloy of some of those metals, or other suitable material, for example.

In the tuning fork piezoelectric vibrator 41 of the present modification example, the piezoelectric layer 42 and the detector electrodes 44, 45 are provided. Thus, a detection signal for angular velocity may be obtained on the upper surface side of the tuning fork piezoelectric vibrator 41. Furthermore, the detecting sensitivity is improved since the piezoelectric layer 42 is provided.

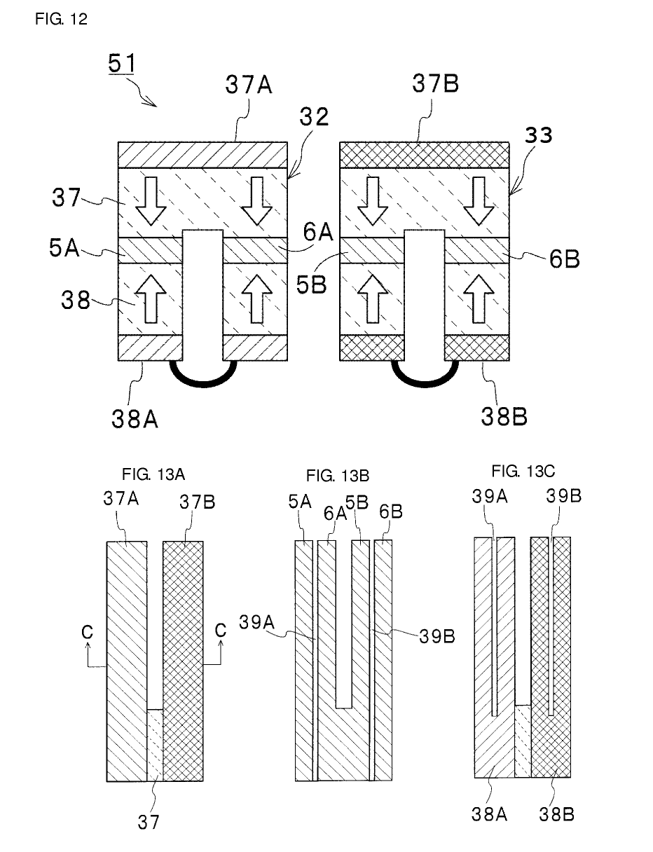

FIG. 12 is a cross-sectional view of a tuning fork piezoelectric vibrator according to a fourth preferred embodiment of the present invention. FIG. 13A to FIG. 13C are schematic plan views illustrating electrode configurations of the tuning fork piezoelectric vibrator at different height positions. FIG. 12 illustrates the cross section cut along the C-C line in FIG. 13A.

A tuning fork piezoelectric vibrator 51 according to the fourth preferred embodiment has a structure similar to that of the foregoing tuning fork piezoelectric vibrator 31. A difference is that, as illustrated in FIG. 13A, the first outer electrode provided on the top surface of the piezoelectric body is divided into two first outer electrodes 37A, 37B. In other words, the first outer electrode is divided into the first outer electrode 37A provided on the first leg portion 32 and the first outer electrode 37B provided on the second leg portion 33. Furthermore, the first inner driver electrode 5B and the second inner driver electrode 6A are connected at the base portion. The remaining aspects are the same as those of the tuning fork piezoelectric vibrator 31. Thus, like reference numerals denote like elements and descriptions thereof are omitted.

However, when the tuning fork piezoelectric vibrator 51 is used as a vibrator of vibrating gyroscope, the first leg portion 32 and the second leg portion 33 are driven in opposite phases in driving mode. In other words, when driving, the first inner driver electrode 5A of the first leg portion 32 and the second inner driver electrode 6B provided in the second leg portion 33 are kept at the same electric potential. Furthermore, the first inner driver electrode 5B and the second inner driver electrode 6A, which are located on inner sides, are kept at the same electric potential. Furthermore, the electric potential of the first inner driver electrodes 5A and the second inner driver electrode 6B is different from the electric potential of the second inner driver electrodes 6A and the first inner driver electrode 5B.

Furthermore, the first outer electrode 37A is not electrically connected to the first outer electrode 37B. The first outer electrodes 37A, 37B and the outer electrodes 38A, 38B provided on the bottom surfaces of the first and second leg portions 32, 33 are preferably used as the detector electrodes.

Thus, in the tuning fork piezoelectric vibrator 51 of the present preferred embodiment, the oscillation occurs by driving such that a state where the first leg portion 32 and the second leg portion 33 move away from each other and a state where the first leg portion 32 and the second leg portion 33 move closer to each other are repeated alternately.

When detecting, a signal may be obtained in response to an angular velocity at between the first outer electrodes 37A, 37B and the outer electrodes 38A, 38B.

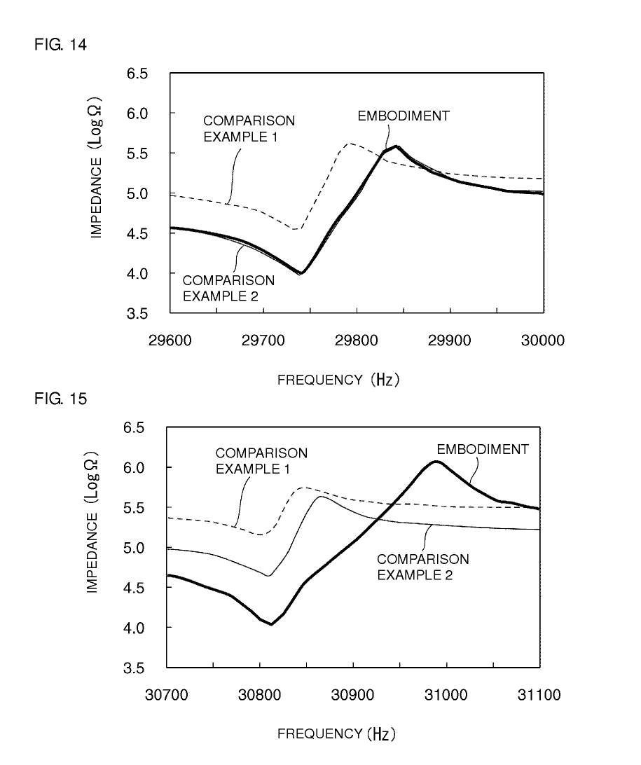

FIG. 14 and FIG. 15 are diagrams illustrating impedance characteristics in driving mode and detecting mode for the tuning fork piezoelectric vibrator 51 of the present preferred embodiment.

For comparison, the impedance characteristics in driving mode and detecting mode are also measured for the following comparison example 1 and comparison example 2. Results are illustrated in FIG. 14 and FIG. 15.

Comparison Example 1 has a structure similar to the tuning fork piezoelectric vibrator 1001 except that the electrodes 1011, 1012, and 1013 are used as the driver electrodes and the detector electrodes and that the inner floating electrode 1010 is used as the floating electrode.

Comparison Example 2 has a structure in which two layers of the piezoelectric layer 1008 of the tuning fork piezoelectric vibrator 1001 are stacked on top of each other and the electrodes 1011, 1012, and 1013 are used as the driver electrodes and the detector electrodes. The two layers of the piezoelectric layers are symmetrically arranged with respect to the line of the inner floating electrode 1010.

As is evident from FIG. 14, peak-to-valley ratios in the impedance characteristics of the foregoing preferred embodiment and the comparison example 2 are substantially the same during the driving mode whereas the peak-to-valley ratio is much smaller in the comparison example 1. Here, the peak-to-valley ratio is a ratio of impedance at an anti-resonant frequency to impedance at a resonant frequency. A larger peak-to-valley ratio indicates a higher driving efficiency. Accordingly, as is evident from FIG. 14, the present preferred embodiment effectively improves the driving efficiency compared to the comparison example 1.

Furthermore, as is evident from FIG. 15, a much larger peak-to-valley ratio is obtained in the present preferred embodiment during the detecting mode compared to the comparison example 1 and the comparison example 2. Accordingly, the present preferred embodiment significantly improves the efficiency during the detecting mode.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A tuning bar piezoelectric vibrator comprising:
a first piezoelectric layer polarized in a thickness direction;
a second piezoelectric layer polarized in a direction opposite to the first piezoelectric layer in the thickness direction, the second piezoelectric layer being stacked on the first piezoelectric layer;
a first inner driver electrode and a second inner driver electrode located between the first and second piezoelectric layers, the first inner driver electrode and the second inner driver electrode being separated from each other in a plane direction of an interface between the first and second piezoelectric layers;
a first outer electrode located on an outer surface of the first piezoelectric layer so as to face the inner driver electrode over the first piezoelectric layer; and
a second outer electrode located on an outer surface of the second piezoelectric layer so as to face the inner driver electrode over the second piezoelectric layer.

2. The tuning bar piezoelectric vibrator according to claim 1, wherein the first inner driver electrode and the second inner driver electrode are arranged at different positions in a direction perpendicular or substantially perpendicular to the interface.

3. The tuning bar piezoelectric vibrator according to claim 1, further comprising a characteristic adjustment layer located on at least one of outer sides of the first and second outer electrodes, the characteristic adjustment layer being made of a material different from or a same as that of the first and second piezoelectric layers.

4. The tuning bar piezoelectric vibrator according to claim 1, further comprising:
a first conduction member; wherein
a groove is arranged so as to extend in the thickness direction of the second piezoelectric layer and penetrate through at least the second piezoelectric layer;
the second piezoelectric layer is divided into a first division piezoelectric layer portion and a second division piezoelectric layer portion by the groove;
the second outer electrode includes a first division outer electrode and a second division outer electrode provided on outer surfaces of the first division piezoelectric layer portion and the second division piezoelectric layer portion; and
the first conduction member defines a conduction path between the first division outer electrode and the second division outer electrode.

5. The tuning bar piezoelectric vibrator according to claim 4, further comprising:
a second conduction member; wherein
the groove is arranged so as to penetrate through the first and second piezoelectric layers;
the first piezoelectric layer is divided into a third division piezoelectric layer portion and a fourth division piezoelectric layer portion by the groove;
the groove includes a jointing material layer that joins the first division piezoelectric layer portion and the third division piezoelectric layer portion to the second division piezoelectric layer portion and the fourth division piezoelectric layer portion;
the first outer electrode is divided into a third division outer electrode and a fourth division outer electrode with the groove in between; and
the second conduction member is arranged to provide an electrical contact between the third and fourth division outer electrodes.

6. A tuning fork piezoelectric vibrator having a tuning fork shape, comprising:
a first leg portion and a second leg portion extending in a length direction, the first leg portion and the second leg portion facing each other along a groove; and
a base portion connected to first ends of the first leg portion and the second leg portion; wherein
a structure including the first leg portion and the second leg portion is defined by tuning bar piezoelectric vibrators, at least one of which is the tuning bar piezoelectric vibrator according to claim 1.

7. The tuning fork piezoelectric vibrator according to claim 6, wherein the first leg portion and the second leg portion are each defined by the tuning bar piezoelectric vibrator according to claim 1.

8. The tuning fork piezoelectric vibrator according to claim 6, wherein
the tuning bar piezoelectric vibrator further includes a first conduction member; wherein
the groove is arranged so as to extend in the thickness direction of the second piezoelectric layer and penetrate through at least the second piezoelectric layer;
the second piezoelectric layer is divided into a first division piezoelectric layer portion and a second division piezoelectric layer portion by the groove;
the second outer electrode includes a first division outer electrode and a second division outer electrode located on outer surfaces of the first division piezoelectric layer portion and the second division piezoelectric layer portion;
the first conduction member defines a conduction path between the first division outer electrode and the second division outer electrode;
the first leg portion includes the first division piezoelectric layer portion and the first division outer electrode located on one side of the groove; and
the second leg portion includes the second division piezoelectric layer portion and the second division outer electrode located on the other side of the groove;
the first and second leg portions are made of a single piece of the tuning bar piezoelectric vibrator.

9. The tuning fork piezoelectric vibrator according to claim 7, further comprising:
a second conduction member; wherein
the groove is arranged so as to penetrate through the first and second piezoelectric layers;
the first piezoelectric layer is divided into a third division piezoelectric layer portion and a fourth division piezoelectric layer portion by the groove;
the groove includes a jointing material layer that joins the first division piezoelectric layer portion and the third division piezoelectric layer portion to the second division piezoelectric layer portion and the fourth division piezoelectric layer portion;
the first outer electrode is divided into a third division outer electrode and a fourth division outer electrode with the groove in between; and
the second conduction member is arranged to provide an electrical contact between the third and fourth division outer electrodes.

10. The tuning fork piezoelectric vibrator according to claim 6, wherein:
the tuning fork piezoelectric vibrator is for use in a gyroscope module to detect a rotational angular velocity;
the inner driver electrode is a driver electrode; and
at least one of the first and second outer electrodes is a detector electrode.

11. The tuning bar piezoelectric vibrator according to claim 1, wherein:
the tuning bar piezoelectric vibrator is for use in a gyroscope module to detect a rotational angular velocity;
the inner driver electrode is a driver electrode; and
at least one of the first and second outer electrodes is a detector electrode.

12. The tuning bar piezoelectric vibrator according to claim 1, further comprising a piezoelectric body having an elongated strip shape.

13. The tuning bar piezoelectric vibrator according to claim 12, wherein the first and second inner driver electrodes are exposed at an outer surface of the piezoelectric body.

14. The tuning bar piezoelectric vibrator according to claim 12, wherein the first and second outer electrodes are arranged so as to cover entire areas of a top surface and a bottom surface of the piezoelectric body.

15. The tuning bar piezoelectric vibrator according to claim 1, wherein the first inner driver electrode and the second inner driver electrode are arranged to receive different electric potentials.

16. The tuning bar piezoelectric vibrator according to claim 12, wherein the piezoelectric body includes a plurality of piezoelectric green sheets stacked on each other.

17. The tuning bar piezoelectric vibrator according to claim 16, wherein the first inner driver electrode and the second inner driver electrode are located on different ones of the plurality of piezoelectric green sheets.

18. The tuning bar piezoelectric vibrator according to claim 1, wherein the first and second piezoelectric layers have different thicknesses in a first vibrator portion and a second vibrator portion.

19. A gyroscope module to detect a rotational angular velocity comprising the tuning bar piezoelectric vibrator of claim 1.

20. A gyroscope module to detect a rotational angular velocity comprising the tuning fork piezoelectric vibrator of claim 6.
